(19) United States
(12) Patent Application Publication
(10) Pub. No.: US 2011/0198597 A1
(43) Pub. Date: Aug. 18, 2011

(54) ORGANIC LIGHT-EMITTING DISPLAY DEVICE AND METHOD OF MANUFACTURING ORGANIC LIGHT-EMITTING DISPLAY DEVICE

(76) Inventors: Dmitry Antonenkov, Yongin-City (KR); Tae-Yong Noh, Yongin-City (KR); Sang-Hun Park, Yongin-City (KR); Hyea-Weon Shin, Yongin-City (KR); Young-Mok Son, Yongin-City (KR); Dong-Won Lee, Yongin-City (KR); Young-Il Kim, Yongin-City (KR); Seong-Ho Kim, Yongin-City (KR)

(21) Appl. No.: 13/028,547

(22) Filed: Feb. 16, 2011

(30) Foreign Application Priority Data
Feb. 16, 2010 (KR) 10-2010-0013842

(51) Int. Cl. H01L 51/52; H01L 51/56

(52) U.S. Cl. 257/59; 438/34; 257/E51.018

(57) ABSTRACT

An organic light emitting display device includes at least one thin film transistor (TFT) on a substrate, the at least one TFT including a semiconductor active layer, a gate electrode insulated from the semiconductor active layer, and source and drain electrodes contacting the semiconductor active layer, a plurality of first electrodes electrically connected to the at least one TFT, a plurality of banks between the plurality of first electrodes, a plurality of organic layers on respective first electrodes, a plurality of second electrodes on respective organic layers, the second electrodes being separated from each other, and a connection electrode on the plurality of banks and the plurality of second electrodes, the connection electrode being electrically connected to the plurality of the second electrodes.

### BACKGROUND

1. Field

Example embodiments relate to an organic light emitting display device, and a method of manufacturing the organic light emitting display device. More particularly, example embodiments relate to an organic light emitting display device in which an organic layer is accurately and easily formed, and a method of manufacturing the organic light emitting display device.

2. Description of the Related Art

An organic light emitting display device is a self emission type display device that emits light by electrically exciting a phosphor organic compound. The organic light emitting device can be driven at a low voltage, can be easily made to be thin, and has advantages such as a wide viewing angle, a good contrast, and a fast response speed. Thus, organic light emitting display devices are highlighted as next generation display devices.

The organic light emitting display device includes a light emitting layer including an organic material between an anode and a cathode. The light emitting layer may be formed using a deposition method, e.g., a deposition via a fine metal mask (FMM) method, a laser induced thermal imaging (LITI) method, or an inkjet printing method. In the organic light emitting device, as positive and negative voltages are applied to the anode and the cathode, injected holes are moved from the anode to the light emitting layer through a hole transport layer, and electrons are moved from the cathode to the light emitting layer through an electron transport layer, so the holes and electrons are recombined with each other to generate excitons.

As the excitons change from an excited state to a ground state, phosphor molecules of the light emitting layer emit light to form an image. A full-color type organic light emitting display device includes pixels for realizing red (R), green (G), and blue (B) colors, thereby realizing full color.

### SUMMARY

Embodiments are therefore directed to an organic light emitting display device and a method of manufacturing the same, which substantially overcome one or more of the problems due to the limitations and disadvantages of the related art.

It is therefore a feature of an embodiment to provide an organic light emitting display device in which an organic layer is accurately and easily formed, and a method of manufacturing the organic light emitting display device.

At least one of the above and other features and advantages may be realized by providing an organic light emitting display device, including at least one thin film transistor (TFT) on a substrate, the at least one TFT including a semiconductor active layer, a gate electrode insulated from the semiconductor active layer, and source and drain electrodes contacting the semiconductor active layer, a plurality of first electrodes electrically connected to the at least one TFT, a plurality of banks between the plurality of first electrodes, a plurality of organic layers on respective first electrodes, a plurality of second electrodes on respective organic layers, the second electrodes being separated from each other, and a connection electrode on the plurality of banks and the plurality of second electrodes, the connection electrode being electrically connected to the plurality of the second electrodes.

The plurality of banks may be formed to cover edges of the plurality of first electrodes.

The plurality of banks may be formed to have a thickness equal to or greater than about 10 μm.

Each of the plurality of organic layers and each of the plurality of second electrodes may be formed between two neighboring banks.

The organic layers and respective second electrodes may be sequentially arranged only in regions between two neighboring banks.

The connection electrode may be a continuous electrode extending conformally on the banks and on the second electrodes.

Each second electrode may be between the connection electrode and a respective organic layer.

The second electrodes may completely overlap respective organic layers.

At least one of the above and other features and advantages may also be realized by providing a method of manufacturing an organic light emitting display device, including forming at least one TFT on a substrate, the at least one TFT including a semiconductor active layer, a gate electrode insulated from the semiconductor active layer, and source and drain electrodes contacting the semiconductor active layer, foaming a plurality of first electrodes electrically connected to the at least one TFT, forming a plurality of banks between the plurality of first electrodes, forming a plurality of organic layers on respective first electrodes, forming a plurality of second electrodes on respective organic layers, such that the second electrodes are separated from each other, and forming a connection electrode on the plurality of banks and the plurality of second electrodes, such that the connection electrode is electrically connected to the plurality of the second electrodes.

The forming of the plurality of banks between the plurality of first electrodes may include forming the plurality of banks so as to cover edges of the plurality of first electrodes.

The forming of the plurality of organic layers may include forming each organic layer between two neighboring banks.

The forming of the plurality of second electrodes on the plurality of organic layers so as to be separated from each other may include forming each second electrode between two neighboring banks.

The plurality of banks may be formed to have a substantially larger thickness than the organic layers, as measured along a normal to the substrate.

The forming of the plurality of organic layers on the plurality of first electrodes may include forming the plurality of organic layers by using an inkjet printing method.

The forming of the plurality of second electrodes on the plurality of organic layers so as to be separated from each other may include forming the plurality of second electrodes by using a sputtering method or a thermal evaporation method.

The forming of the connection electrode may be performed using any one of a chemical vapor deposition (CVD) method, a plasma enhanced (PE) CVD method, and an electron cyclotron resonance (ECR) CVD method.

In the forming of the connection electrode, the plurality of second electrodes may protect the plurality of organic layers from chemically active particles generated during the CVD method.

### BRIEF DESCRIPTION OF THE DRAWINGS

The above and other features and advantages will become more apparent to those of ordinary skill in the art by describing in detail exemplary embodiments with reference to the attached drawings, in which:

FIG. 1 illustrates a schematic cross-sectional view of an organic light emitting display device according to an embodiment; and

FIGS. 2A through 2G illustrate cross-sectional views of stages in a method of manufacturing an organic light emitting display device according to an embodiment.

### DETAILED DESCRIPTION

Korean Patent Application No. 10-2010-0013842, filed on Feb. 16, 2010, in the Korean Intellectual Property Office, and entitled: “Organic Light-Emitting Display Device and Method of Manufacturing Organic Light-Emitting Display Device,” is incorporated by reference herein in its entirety.

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer (or element) is referred to as being “on” another layer or substrate, it can be directly on the other layer or substrate, or intervening layers may also be present. In addition, it will also be understood that when a layer is referred to as being “between” two layers, it can be the only layer between the two layers, or one or more intervening layers may also be present. Like reference numerals refer to like elements throughout.

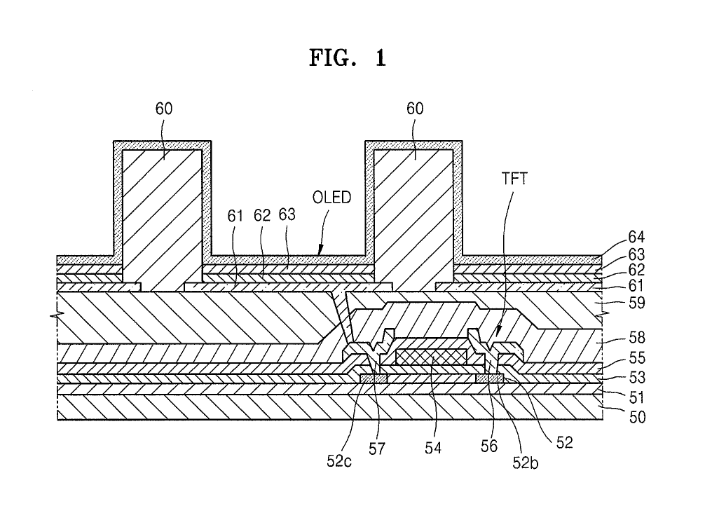

FIG. 1 illustrates a schematic cross-sectional view of an organic light emitting display device according to an embodiment. Referring to FIG. 1, a thin film transistor (TFT) and an organic light emitting element, e.g., an organic light emitting diode (OLED), may be formed on a substrate 50. FIG. 1 illustrates a portion of one pixel of the organic light emitting display device. The organic light emitting display device includes a plurality of such pixels.

A buffer layer 51 may be formed on the substrate 50, e.g., a glass or plastic substrate, and an active layer 52 having a predetermined pattern may be formed on the buffer layer 51. A gate insulating layer 53 may be disposed on the active layer 52, and a gate electrode 54 may be formed in a predetermined region of the gate insulating layer 53. The gate electrode 54 is connected to a gate line (not shown) for applying a TFT on/off signal. An interlevel insulating layer 55 may be formed on the gate electrode 54, and source/drain electrodes 56 and 57 may be formed to contact source/drain regions 52b and 52c, respectively, of the active layer 52 through contact holes. A passivation layer 58 may be formed of, e.g., SiO₂, SiNₓ, or the like, on the source/drain electrodes 56 and 57. A planarization layer 59 may be formed of an organic material, e.g., acryl, polyimide, benzocyclobutene (BCB), or the like, on the passivation layer 58. A first electrode 61 functioning as an anode of the OLED may be formed on the planarization layer 59, and banks 60 may be formed so as to cover both ends, e.g., opposite edges, of the first electrode 61. An organic layer 62 may be formed on the first electrode 61 in a region defined by the banks 60, e.g., between two adjacent banks 60. The organic layer 62 may include a light-emitting layer. It is noted that example embodiments are not limited to the structure described above, and various structures of organic light-emitting display devices may be applied to the example embodiments.

The OLED displays predetermined image information by emitting red, green and blue light as current flows therethrough. The OLED includes the first electrode 61, the second electrode 63, and the organic layer 62 therebetween. The first electrode 61 is connected to the drain electrode 56 of the TFT and is applied with a positive power voltage, the second electrode 63 covers an entire sub-pixel and is applied with a negative power voltage, and the organic layers 62 emits light. The first electrodes 61 and the second electrodes 63 are insulated from each other by the organic layers 62, and respectively apply voltages of opposite polarities to the organic layers 62 to induce light emission in the organic layers 62.

The organic layers 62 may be formed of a low-molecular weight organic material or a high-molecular weight organic material. When a low-molecular weight organic material is used, the organic layer 62 may have a single or multi-layer structure including at least one of a hole injection layer (HIL), a hole transport layer (HTL), an emission layer (EML), an electron transport layer (ETL), and an electron injection layer (EIL). Examples of suitable organic materials may include copper phthalocyanine (CuPc), N,N-di(naphthalene-1-yl)-N,N-diphenyl-benzidine (NPB), and tris-8-hydroxyquinoline aluminum (Alq3). The low-molecular weight organic layer may be formed by performing, e.g., vacuum deposition.

When a high-molecular weight organic layer is used as the organic layer 62, the organic layer 62 may have a structure mostly including a HTL and an EML. In this case, the HTL may be formed of, e.g., poly(ethylenedioxythiophene) (PEDOT), and the EML may be formed of, e.g., polyphenylenevinylenes (PPVs) or polyfluorenes. The HTL and the EML may be formed by performing, e.g., screen printing, inkjet printing, or the like. It is noted, however, that the organic layer 62 is not limited to the organic layers described above, and may be embodied in various other ways.

The first electrode 61 may function as an anode, and the second electrode 63 may function as a cathode. Alternatively, the first electrode 61 may function as a cathode, and the second electrode 63 may function as an anode. The second electrode 63 may be formed separately in each sub-pixel, e.g., each second electrode 63 may be discontinuous with respect to an adjacent second electrode 63 in an adjacent sub-pixel. As illustrated in FIG. 1, the separate second electrodes 63 may be connected to each other via a connection electrode 64 on the second electrodes 63 and the banks 60, as will be described in more detail below.

The first electrode 61 may be formed as a transparent electrode or a reflective electrode. Such a transparent electrode may be formed of, e.g., indium tin oxide (ITO), indium zinc oxide (IZO), zinc oxide (ZnO), or indium oxide (In₂O₃). Such a reflective electrode may be formed by forming a reflective layer of, e.g., silver (Ag), magnesium (Mg), aluminum (Al), platinum (Pt), palladium (Pd), gold (Au), nickel (Ni), neodymium (Nd), iridium (Ir), chromium (Cr) or a compound thereof, and forming a layer of, e.g., ITO, IZO, ZnO, or In₂O₃, on the reflective layer.

The second electrode 63 may be formed as a transparent electrode or a reflective electrode. When the second electrode 63 is formed as a transparent electrode, the second electrode 63 functions as a cathode. To this end, such a transparent electrode may be formed by depositing a metal having a low work function, e.g., lithium (Li), calcium (Ca), lithium fluoride/calcium (LiF/Ca), lithium fluoride/aluminum (LiF/Al), aluminum (Al), silver (Ag), magnesium (Mg), or a compound thereof, on a surface of the organic layer 62 and forming an auxiliary electrode layer or a bus electrode line thereon of a transparent electrode forming material, e.g., ITO, IZO, ZnO, In₂O₃, or the like. When the second electrode 63 is a reflective electrode, the reflective layer may be formed by depositing, e.g., Li, Ca, LiF/Ca, LiF/Al, Al, Ag, Mg, or a compound thereof, on the entire surface of the organic layer 62.

As illustrated in FIG. 1, according to an embodiment, the organic light emitting display device may include a plurality of relatively thick banks 60 on edges of the first electrodes 61 in order to facilitate formation of the organic layers 62. For example, the banks 60 may be sufficiently thick in order to use an inkjet printing method for forming the organic layers 62. Accordingly, each of the organic layers 62 and each of the second electrodes 63 may be easily and accurately positioned between neighboring banks 60. In contrast, when a conventional inkjet printing method for forming an organic layer is applied between thin banks, it may be difficult to spray material, i.e., ink, via an inkjet printing method in a fine patterning process between the banks without spreading ink outside a desired region.

Further, the connection electrode 64 may be formed, e.g., conformally, on the second electrodes 63 and banks 60 in order to connect separate second electrodes 63 to each other. As such, even if the second electrodes 63 are separate from each other because of the increased thickness of the banks 60, the second electrodes 63 in all the sub-pixels may be connected to each other via the connection electrode 64.

Thus, according to an embodiment, an organic light emitting display device may include a plurality of relatively thick banks 60 to define regions for forming organic layers and second electrodes easily and accurately. Further, the organic light emitting display device may include a connection electrode 64 in order to connect the second electrodes 63 formed between the banks 60.

In detail, the banks 60 may be formed so as to cover both ends of the first electrodes 61. In this case, the banks 60 may each be formed so as to have a relatively great thickness, e.g., as measured along a direction normal to the substrate 50. The banks 60 may be substantially thicker than a combined thickness of the organic layers 62 and the second electrodes 63. For example, each bank 60 may have a thickness equal to or greater than about 10 μm. By forming each of the banks 60 to have a relatively great thickness compared to the organic layers 62 and the second electrodes 63, the banks 60 may accurately define a position for the organic layer 62, e.g., restrict location of ink drops to an area only between adjacent banks 60. Thus, uniformity of the organic layers 62 on the first electrode 61 may be improved and spreading of the organic layer 62 beyond a desired area may be prevented.

The organic layers 62 and second electrodes 63 may be formed between the neighboring banks 60. In this case, the organic layers 62 may be formed using the above-described inkjet printing method. The second electrodes 63 may be formed on the organic layers 62 so as to cover the organic layers 62, e.g., each second electrode 63 may be formed between the connection electrode 64 and a corresponding organic layer 62. The second electrodes 63 may be formed using, e.g., a sputtering method or a thermal evaporation method. By forming the second electrodes 63 on the organic layers 62 so as to cover the organic layers 62, the organic layers 62 may be prevented from deteriorating during formation of the connection electrode 64, as will be described later.

The connection electrode 64 may be formed on, e.g., directly on, the banks 60 and the second electrodes 63. For example, the connection electrode 64 may be continuous over all the sub-pixels and may contact, e.g., directly contact, each second electrode 63 to connect the second electrodes 63 to each other.

The connection electrode 64 may be formed in a state of gas by using, e.g., a chemical vapor deposition (CVD) method, a plasma enhanced (PE) CVD method, an electron cyclotron resonance (ECR) CVD method, or the like. In this case, the connection electrode 64 may be formed to cover the second electrodes 63, and thus the connection electrode 64 connects the second electrodes 63 to each other.

Since the second electrodes 63 cover the organic layers 62, e.g., completely overlap corresponding organic layers 62, the second electrodes 63 may protect the organic layers 62 from chemically active particles generated during formation of the connection electrode 64 via the CVD method. Likewise, without damaging the organic layers 62, the second electrodes 63 that have equal angles and are electrically connected may be formed by combining the second electrodes 63 and the connection electrode 64.

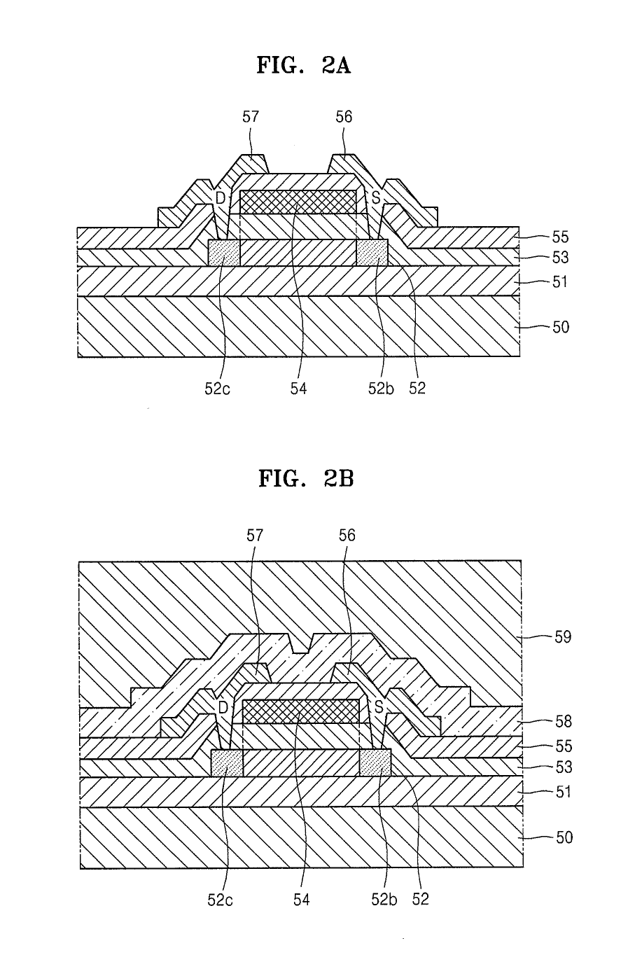

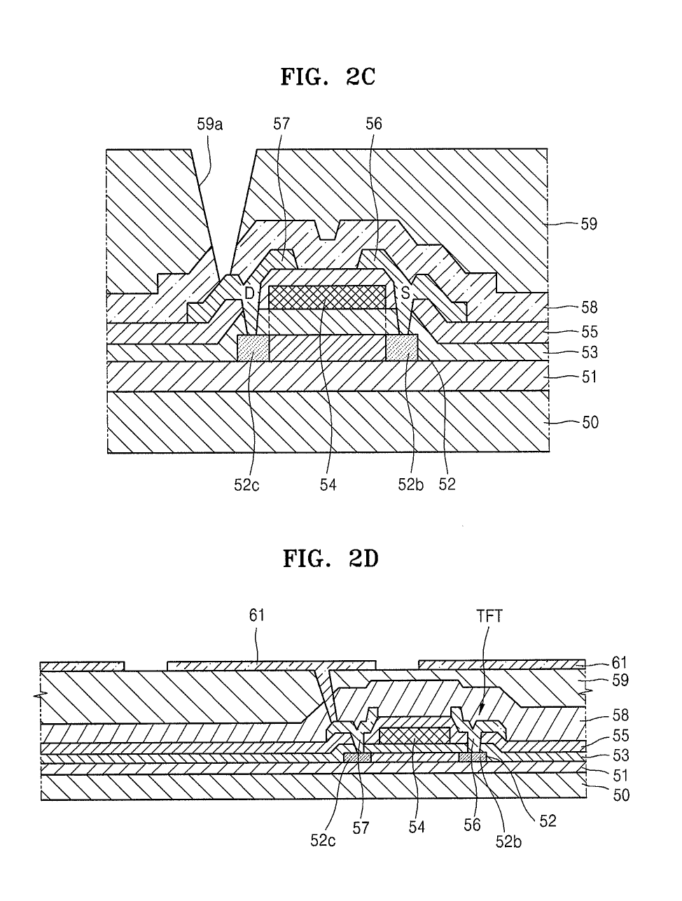

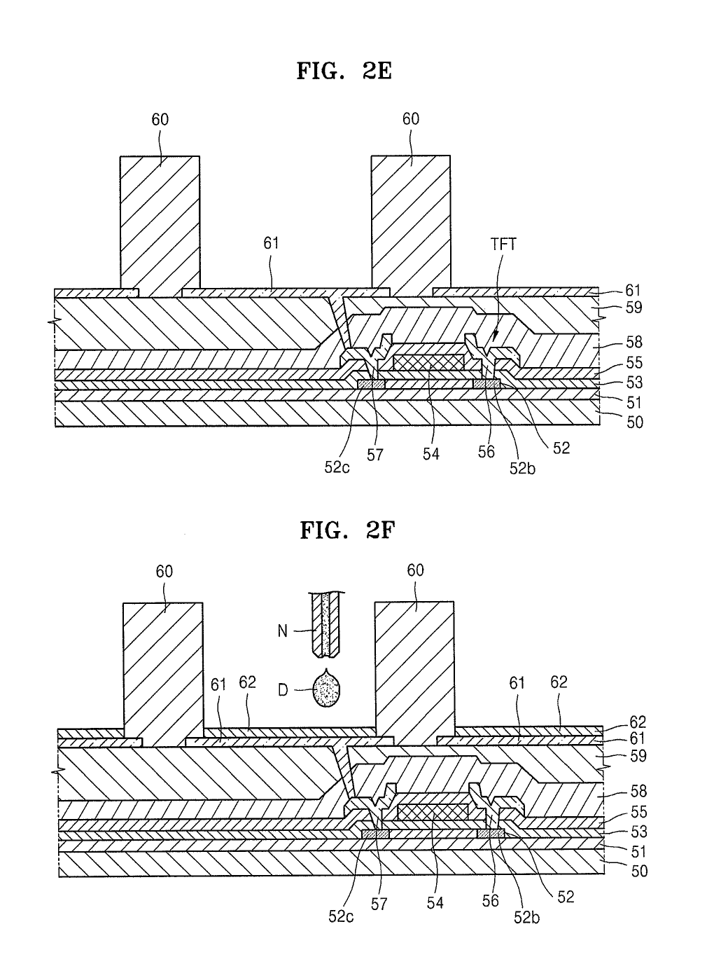

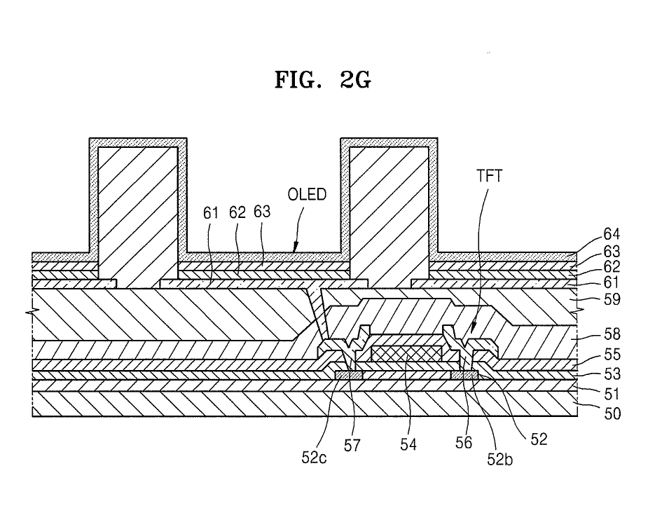

A method of manufacturing an organic light emitting display device according to an embodiment will now be described in detail with reference to FIGS. 2A through 2G. FIGS. 2A through 2G illustrate cross-sectional views of stages in a method of manufacturing the organic light emitting display device of FIG. 1.

Referring to FIGS. 2A through 2G, the method of manufacturing the organic light emitting display device may include forming the TFT, forming the passivation layer 58 and the planarization layer 59 on the TFT, forming an opening 59a in the passivation layer 58 and the planarization layer 59, and forming the first electrodes 61 that are electrically connected to the TFT through the opening 59a. Next, the method may include forming the banks 60 with a relatively great thickness so as to cover the first electrodes 61, forming the organic layers 62 and the second electrodes 63 between the neighboring banks 60, and forming the connection electrode 64 on the banks 60 and the second electrodes 63.

Referring to FIG. 2A, the TFT may be formed on the substrate 50. Formation of the TFT has been described previously with reference to FIG. 1 and, therefore, will not be repeated.

Referring to FIG. 2B, the passivation layer 58 and the planarization layer 59 may be formed on the TFT. The passivation layer 58 may be formed of an inorganic material, e.g., SiO₂, SiNx, or the like, on the source (S) and drain (D) electrodes 56 and 57. The planarization layer 59 may be formed of an organic material, e.g., acryl, polyimide, benzocyclobutene (BCB), or the like, on the passivation layer 58. The passivation layer 58 and the planarization layer 59 may be formed using, e.g., a CVD method, a PE-CVD method, or an ECR-CVD method.

Referring to FIG. 2C, the opening 59a may be formed through the passivation layer 58 and the planarization layer 59. As shown in FIG. 2C, regions of the passivation layer 58 and the planarization layer 59 may be patterned to form the opening 59a and expose a portion of the drain electrode 57.

Referring to FIG. 2D, the first electrodes 61 may be formed on the planarization layer 59. Each first electrode 61 may be electrically connected to a corresponding TFT through the opening 59a.

Referring to FIG. 2E, the banks 60 may be formed so as to cover both ends of the first electrodes 61. For example, each bank 60 may be positioned between two adjacent first electrodes 61 and overlap respective edges of the two adjacent first electrodes 61, e.g., the bank 60 may overlap side and upper surfaces of the first electrode 61. In this case, the banks 60 may be formed by patterning a material such as polyacrylate by using photolithography. The banks 60 may be formed to a relatively great thickness. For example, the banks 60 may each have a thickness equal to or greater than about 10 μm. By forming each of the banks 60 so as to have a relatively great thickness compared to the organic layers 62 and the second electrodes 63, the banks 60 may restrict a location of the ink drops. Thus, uniformity of the organic layer 62 may be improved and spreading of the ink drops beyond a desired area may be prevented.

Referring to FIG. 2F, the organic layers 62 may be formed between the neighboring banks 60. The organic layers 62 may be formed using the above-described inkjet printing method. That is, ink paste drops ‘D’ may be added dropwise onto the first electrodes 61 by an inkjet nozzle ‘N’ to form the organic layers 62. When the ink paste drops ‘D’ are added dropwise in order to print such an ink paste by using an inkjet printing method, the banks 60 with the relatively great thickness may function as a dam to define an accurate position for the ink. Thus, the ink paste drops ‘D’ may be formed in a desired region.

Referring to FIG. 2G, the second electrodes 63 may be formed on respective organic layer 62 between adjacent banks 60. Next, the connection electrode 64 may be formed, e.g., conformally, to cover the second electrodes 63 and the banks 60.

The second electrodes 63 may be formed on the organic layers 62 so as to cover the organic layers 62. The second electrodes 63 may be formed, e.g., using a sputtering method and a thermal evaporation method. By forming the second electrodes 63 on the organic layers 62 so as to cover the organic layers 62, the organic layers 62 may be prevented from deteriorating during formation of the connection electrode 64.

The connection electrode 64 may be fondled on the banks 60 and the second electrodes 63. The connection electrode 64 connects the separate second electrodes 63 to each other. The connection electrode 64 may be formed in a state of gas by using, e.g., a CVD method, a PE-CVD method, an ECR-CVD method, or the like. In this case, the connection electrode 64 may be formed to cover the second electrodes 63, and thus the connection electrode 64 connects the second electrodes 63 to each other.

The second electrodes 63 may protect the organic layers 62 from chemically active particles generated during formation of the connection electrode 64 via the CVD method. Likewise, without damaging the organic layers 62, the second electrodes 63 that have equal angles and are electrically connected may be formed by combining the second electrodes 63 and the connection electrode 64. Therefore, as described above, according to the one or more of the above embodiments, the organic layer 62 may be accurately and easily formed.

Exemplary embodiments have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. An organic light emitting display device, comprising:
at least one thin film transistor (TFT) on a substrate, the at least one TFT including a semiconductor active layer, a gate electrode insulated from the semiconductor active layer, and source and drain electrodes contacting the semiconductor active layer;
a plurality of first electrodes electrically connected to the at least one TFT;
a plurality of banks between the plurality of first electrodes;
a plurality of organic layers on respective first electrodes;
a plurality of second electrodes on respective organic layers, the second electrodes being separated from each other; and
a connection electrode on the plurality of banks and the plurality of second electrodes, the connection electrode being electrically connected to the plurality of the second electrodes.

2. The organic light emitting display device as claimed in claim 1, wherein the plurality of banks covers edges of the plurality of first electrodes.

3. The organic light emitting display device as claimed in claim 1, wherein the plurality of banks have a thickness equal to or greater than about 10 μm.

4. The organic light emitting display device as claimed in claim 1, wherein each of the organic layers and each of the second electrodes is between two neighboring banks.

5. The organic light emitting display device as claimed in claim 4, wherein the organic layers and respective second electrodes are sequentially arranged only in regions between two neighboring banks.

6. The organic light emitting display device as claimed in claim 1, wherein the connection electrode is a continuous electrode extending conformally on the banks and on the second electrodes.

7. The organic light emitting display device as claimed in claim 1, wherein each second electrode is between the connection electrode and a respective organic layer.

8. The organic light emitting display device as claimed in claim 7, wherein the second electrodes completely overlap respective organic layers.

9. A method of manufacturing an organic light emitting display device, the method comprising:
forming at least one thin film transistor (TFT) on a substrate, the at least one TFT including a semiconductor active layer, a gate electrode insulated from the semiconductor active layer, and source and drain electrodes contacting the semiconductor active layer;
forming a plurality of first electrodes electrically connected to the at least one TFT;
forming a plurality of banks between the plurality of first electrodes;
forming a plurality of organic layers on respective first electrodes;
forming a plurality of second electrodes on respective organic layers, such that the second electrodes are separated from each other; and
forming a connection electrode on the plurality of banks and the plurality of second electrodes, such that the connection electrode is electrically connected to the plurality of the second electrodes.

10. The method as claimed in claim 9, wherein forming the plurality of banks between the plurality of first electrodes includes forming the plurality of banks to cover edges of the plurality of first electrodes.

11. The method as claimed in claim 9, wherein forming the plurality of organic layers includes forming each organic layer between two neighboring banks.

12. The method as claimed in claim 11, wherein forming the plurality of second electrodes includes forming each second electrode between two neighboring banks.

13. The method as claimed in claim 9, wherein the plurality of banks is formed to have a substantially larger thickness than the organic layers, as measured along a normal to the substrate.

14. The method as claimed in claim 13, wherein forming the plurality of organic layers includes using an inkjet printing method.

15. The method as claimed in claim 9, wherein forming the plurality of second electrodes includes using a sputtering method or a thermal evaporation method.

16. The method as claimed in claim 9, wherein forming the connection electrode includes using a chemical vapor deposition (CVD) method, a plasma enhanced (PE) CVD method, or an electron cyclotron resonance (ECR) CVD method.

17. The method as claimed in claim 16, wherein, before forming the connection electrode, forming the second electrodes to completely cover the organic layers to protect the organic layers from chemically active particles generated during the CVD method.
